(19) United States
(12) Patent Application Publication
(10) Pub. No.: US 2025/0321478 A1
(43) Pub. Date: Oct. 16, 2025

(54) DETECTION METHOD OF WEAK POINT AND VERIFICATION METHOD OF MASK QUALITY

(71) Applicant: Samsung Electronics Co., Ltd., Suwon-si (KR)

(72) Inventors: Sangchul YEO, Suwon-si (KR); Yongsun JANG, Suwon-si (KR); Hee JEONG, Suwon-si (KR); Jaewon YANG, Suwon-si (KR); Seongtae JEONG, Suwon-si (KR); Dawoon CHOI, Suwon-si (KR)

(73) Assignee: Samsung Electronics Co., Ltd., Suwon-si (KR)

(21) Appl. No.: 19/027,129

(22) Filed: Jan. 17, 2025

(30) Foreign Application Priority Data
Apr. 15, 2024 (KR) 10-2024-0050303

(51) Int. Cl. G03F 1/84

(52) U.S. Cl. CPC G03F 1/84

(57) ABSTRACT

A detection method of weak points may include obtaining large-scale data including contours of a plurality of patterns formed on a wafer using a mask, calculating an average value of critical dimensions of the contours of the plurality of patterns included in the large-scale data, clustering the plurality of patterns into a plurality of clusters based on characteristics of the plurality of patterns, calculating, for each of the plurality of clusters, an average value of the critical dimensions of the contours of the plurality of patterns included in each of the plurality of clusters, and determining whether one or more clusters of the plurality of clusters are weak points based on the average value of the critical dimensions of each of the plurality of clusters and the average value of the critical dimensions of the large-scale data.

### CROSS-REFERENCE TO RELATED APPLICATION

This U.S. non-provisional application is based on and claims the benefit of priority under 35 U.S.C. § 119 to Korean Patent Application No. 10-2024-0050303, filed on Apr. 15, 2024, in the Korean Intellectual Property Office, the disclosure of which is incorporated by reference herein in its entirety.

### BACKGROUND

Various example embodiments of the inventive concepts relate to a method of detecting weak points in a mask and a verification method of mask quality, and more particularly, to a method of detecting weak points related to a photomask and a verification method of mask quality, a system thereof, and/or a device thereof, etc.

In a semiconductor process, a photolithography process using a mask may be performed to form a pattern on a semiconductor substrate, such as a semiconductor wafer. The mask may include a pattern transfer body in which a pattern shape of an opaque material is formed on a transparent base material. To produce such a mask, after designing the layout for the desired and/or required pattern, post-optical proximity correction (OPC) layout data obtained through OPC is generated, delivered, and/or output as mask tape-out (MTO) design data. Afterwards, mask data preparation (MDP) may be performed based on the MTO design data and an exposure process may be performed on the wafer.

### SUMMARY

Various example embodiments of the inventive concepts provide a method of detecting weak points to improve the accuracy of mask verification during a verification method of mask quality, thereby improving the quality of the photolithography process, a mask weak point detection system, and/or a mask weak point device, etc.

In addition, the example embodiments of the inventive concepts are not limited to the mentioned above, and other inventive concepts not mentioned above may be clearly understood by those of ordinary skill in the art from the description below.

According to at least one example embodiment of the inventive concepts, there is provided a detection method of weak points, the method including obtaining large-scale data including contours of a plurality of patterns formed on a wafer using a mask, calculating an average value of critical dimensions of the contours of the plurality of patterns included in the large-scale data, clustering the plurality of patterns into a plurality of clusters based on characteristics of the plurality of patterns, calculating, for each of the plurality of clusters, an average value of the critical dimensions of the contours of the plurality of patterns included in each of the plurality of clusters, and determining whether one or more clusters of the plurality of clusters are weak points based on the average value of the critical dimensions of each of the plurality of clusters and the average value of the critical dimensions of the large-scale data.

According to at least one example embodiment of the inventive concepts, there is provided a detection method of weak points, the method including obtaining large-scale data including contours of a plurality of patterns formed on a wafer using a mask, clustering the plurality of patterns into a plurality of clusters based on characteristics of the plurality of patterns, calculating, for each respective cluster of the plurality of clusters, an average value of critical dimensions of the contours of the plurality of patterns included in the respective cluster, visualizing each of the plurality of clusters as an image, the visualizing including for each respective cluster of the plurality of clusters, overlapping the contours of the plurality of patterns included in the respective cluster, and determining whether one or more of the plurality of clusters include weak points based on the average value of the critical dimensions of each of the plurality of clusters and the average value of the critical dimensions of the large-scale data.

According to at least one example embodiment of the inventive concepts, there is provided a verification method of mask quality, the method including forming a plurality of patterns on a wafer through a photolithography process using a mask, obtaining basic data of the plurality of patterns formed on the wafer, detecting weak points based on the basic data, and determining whether the mask is defective based on the detected weak points, the detecting of the weak points including, obtaining large-scale data including contours of the plurality of patterns formed on the wafer using the mask, calculating an average value of critical dimensions of the contours of the plurality of patterns included in the large-scale data, clustering the plurality of patterns into a plurality of clusters based on characteristics of the plurality of patterns, calculating, for each respective cluster of the plurality of clusters, an average value of the critical dimensions of the contours of the plurality of patterns included in the respective cluster, and determining whether one or more of the plurality of clusters are weak points based on the average value of the critical dimensions of each of the plurality of clusters and the average value of the critical dimensions of the large-scale data.

### BRIEF DESCRIPTION OF THE DRAWINGS

Various example embodiments will be more clearly understood from the following detailed description taken in conjunction with the accompanying drawings in which:

FIG. 1 is a schematic flowchart of a verification method of mask quality according to at least one example embodiment;

FIG. 2 is a schematic flowchart of a detection method of weak points according to at least one example embodiment;

FIG. 3 is a schematic plan view of a wafer on which a plurality of patterns are formed according to at least one example embodiment;

FIG. 4 is a diagram schematically showing large-scale data obtained by measuring a portion of the wafer of FIG. 3 according to at least one example embodiment;

FIG. 5 is a schematic graph showing uniformity of critical dimensions of contours of a plurality of patterns included in the large-scale data of FIG. 4 according to at least one example embodiment;

FIG. 6 is a diagram showing contours of a plurality of patterns included in the large-scale data of FIG. 4 as a plurality of clusters according to at least one example embodiment;

FIG. 7 is a schematic graph showing uniformity of critical dimensions of contours of a plurality of patterns included in each of the plurality of clusters in FIG. 6 according to at least one example embodiment;

FIG. 8 is a schematic flowchart of a detection method of weak points according to at least one example embodiment;

FIG. 9 is a schematic graph showing an average value of critical dimensions for each cluster according to at least one example embodiment;

FIG. 10 is a schematic flowchart of a detection method of weak points according to at least one example embodiment; and

FIG. 11 is a diagram showing a process of visualizing each of a plurality of clusters according to at least one example embodiment.

FIG. 12 is a block diagram showing a mask weak point detection system according to at least one example embodiment.

### DETAILED DESCRIPTION

Since the example embodiments are subject to various changes and have various forms, some example embodiments are illustrated in the drawings and described in detail. However, this is not intended to limit the example embodiments to the specific disclosure form.

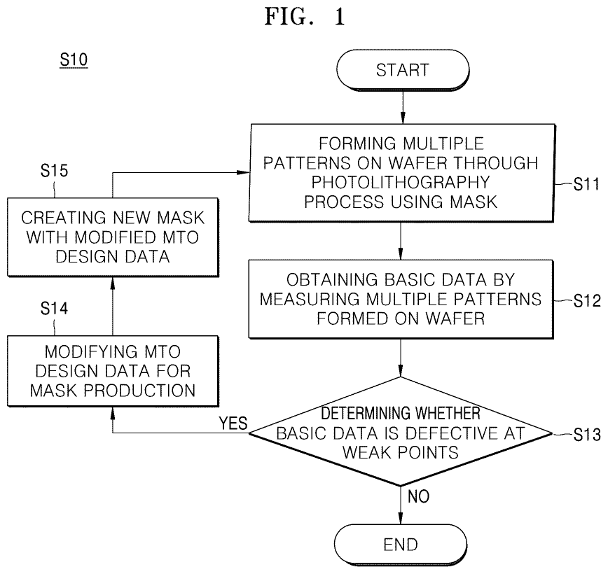

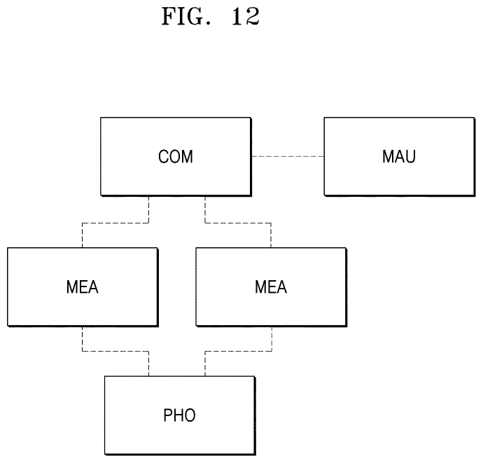

FIG. 1 is a schematic flowchart of a verification method of mask quality S10 according to at least one example embodiment. FIG. 12 is a block diagram showing a mask weak point detection system according to at least one example embodiment.

Referring to FIG. 1, the verification method of mask quality S10 may include forming a plurality of patterns on a wafer through a photolithography process using a mask (S11), obtaining basic data by measuring the plurality of patterns formed on the wafer (S12), and/or determining whether the basic data is defective at one or more weak points (S13), or in other words, the basic data may be analyzed to determine whether the plurality of patterns includes one or more weak points, etc., but the example embodiments are not limited thereto. When the basic data is determined to be defective, the verification method of mask quality S10 may further include modifying mask tape-out (MTO) design data for mask production S14 and creating a new mask (and/or a new mask design) with the modified MTO design data S15, but is not limited thereto. When the basic data is not defective, the mask may pass a mask quality test, e.g., the mask quality is verified.

Referring to FIG. 12, the mask weak point detection system may comprise a computer including processing circuitry executing computer COM readable instructions for performing the operations of the recited methods, and the machinery MAU which manufactures a mask, and the machinery PHO which performs the photolithography processes to wafer with the mask, and measuring devices MEA which measure the wafer and communicatively connected to the computer. For example, the measuring devices MEA may include at least one of scanning electron microscope (SEM) and Nano Geometry Research (NGR) device.

Generally, to form one or more patterns on a wafer a layout for the patterns on the mask may be created and/or generated first. The patterns may refer to at least one pattern formed by transferring the layout (e.g., the physical features, etc.) of the mask onto the wafer through a doping process and/or an exposure process, and the shape of the resulting pattern may be different from the layout on the mask due to the nature of the doping and/or exposure process(es). In addition, the layout on the mask may be scaled down before being transferred onto the wafer, and therefore the layout on the mask may have a larger size than the resulting pattern on the wafer.

As the patterns become more refined, complex, and/or smaller in size, an optical proximity effect (OPE) may occur due to the influence between neighboring patterns during the doping and/or exposure process(es). Thus, optical proximity correction (OPC) may be performed to decrease and/or suppress the occurrence of OPEs by correcting the layout on the mask. The post-OPC layout may correspond to design data. The post-OPC layout may be delivered to a mask production team as MTO design data for mask production.

For the mask produced by the mask production team based on the MTO design data, an additional mask quality verification process may be performed to improve the mask quality and/or ensure that the mask may actually form the desired patterns on the wafer, etc. Patterns may be formed on the wafer using the mask produced based on the MTO design data.

Afterwards, basic data may be obtained by measuring the patterns formed on the wafer. For example, the basic data on the wafer may be obtained by measuring the patterns formed on the wafer through, e.g., a scanning electron microscope (SEM) device and/or Nano Geometry Research (NGR) device, etc., but the example embodiments are not limited thereto.

Afterwards, whether the basic data is defective at the weak points may be determined. For example, the weak points may be referred to as weak patterns. Because the types and number of patterns formed on the wafer vary, it may take considerable cost and/or time to determine whether all patterns are defective. Therefore, among the patterns formed on the wafer, only patterns at weak points where defects frequently occur may be used to determine whether they are defective.

The verification method of mask quality S10 may further include detecting weak points in the mask design. For example, the detecting of the weak points may be the same and/or substantially the same as the detection method of weak points to be described below, but is not limited thereto. As the verification method of mask quality S10 is additionally performed during the process of detecting weak points, additional weak points other than the pre-stored weak points may also be subject to mask quality verification. Accordingly, the accuracy of mask quality verification may be improved.

In some example embodiments, the weak points and/or pre-stored weak points may include weak points detected through simulation, weak points stored in a weak point library, weak points determined based on experiential data and/or experimental data, and/or determined unique weak points for each mask, etc., but the example embodiments are not limited thereto. For example, the simulation may include an optical rule check (ORC). The detection method of additional weak points may be described below.

In addition, in the mask quality verification process, the accuracy of the patterns may be verified by measuring the local area of the wafer using, e.g., an SEM device, etc., and the uniformity of the critical dimensions (CD) of a plurality of patterns may be verified by measuring the large area of the wafer using the NGR device, but is not limited thereto.

When the patterns formed on the wafer are determined to be defective, the MTO design data associated with and/or corresponding to the original manufactured mask may be modified and a new mask (and/or modified mask, etc.) may be manufactured using the modified MTO design data. With the newly manufactured mask, new patterns may be formed on the wafer again (and/or new patterns may be formed on a new wafer, etc.), and the new mask design may be verified to determine whether it is defective. When the patterns formed on the wafer are determined to not be defective (and/or the patterns on the wafer are determined to not include weak points, etc.), the mask may pass the mask quality test.

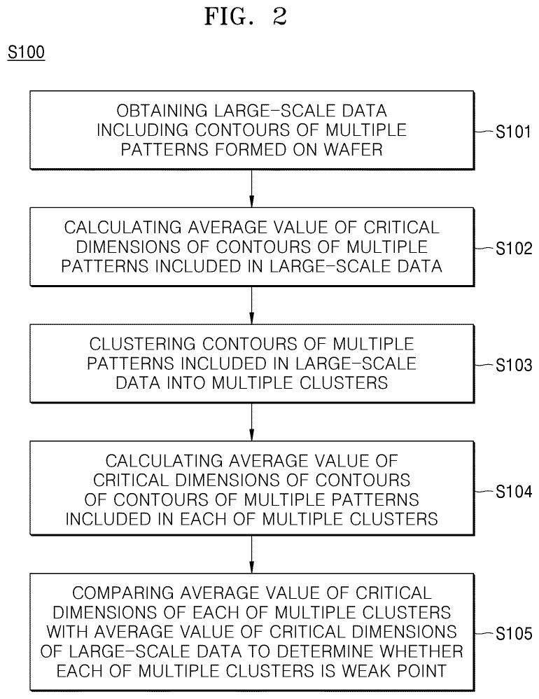

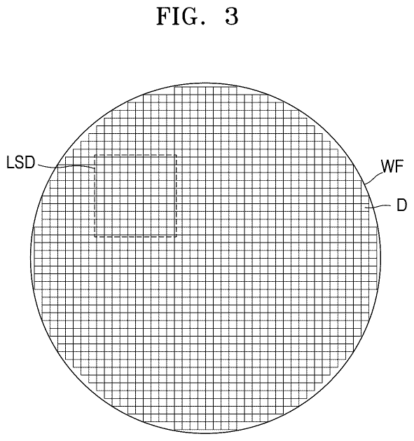

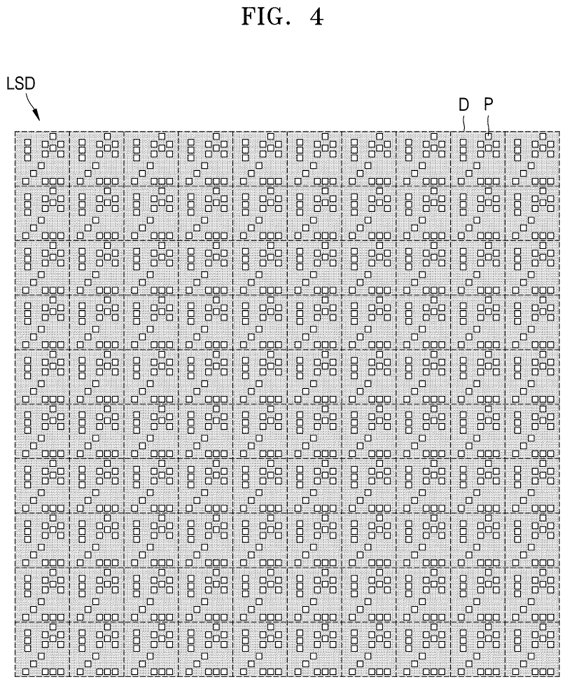

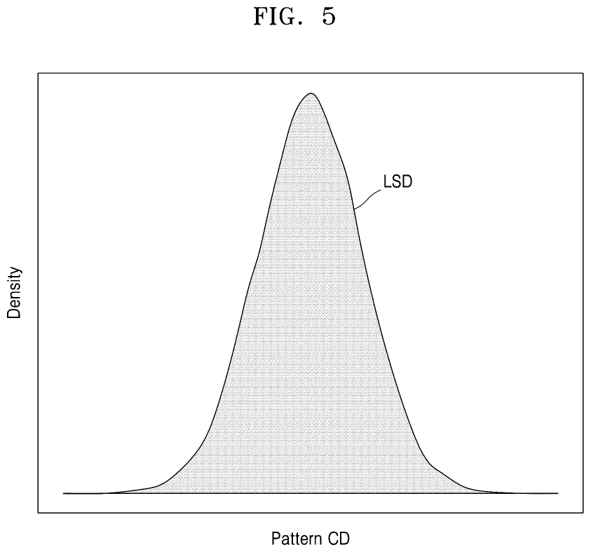

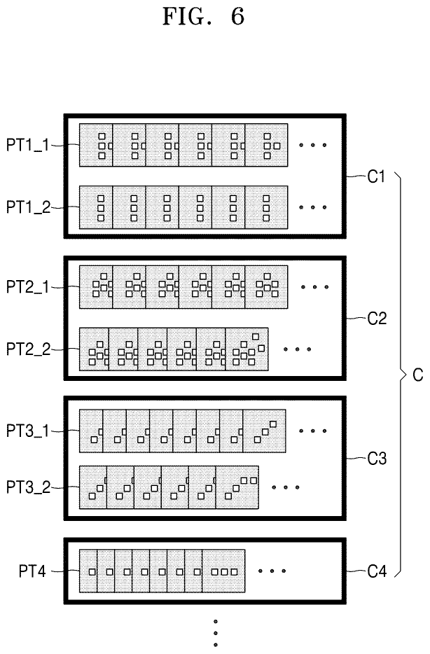

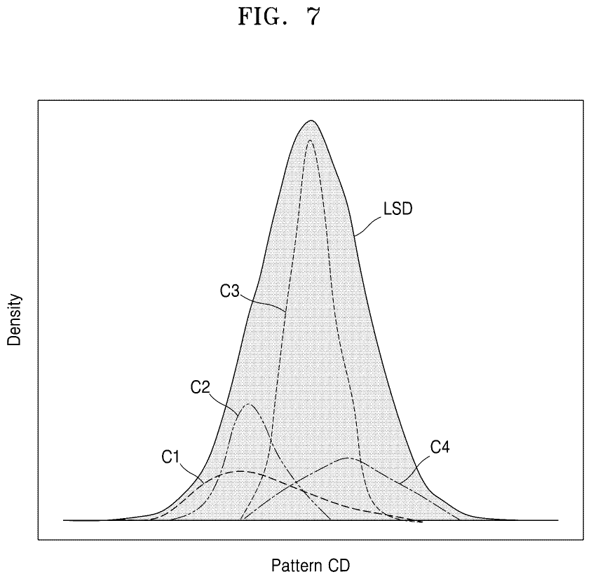

FIG. 2 is a schematic flowchart of a detection method of weak points S100 according to at least one example embodiment. FIG. 3 is a schematic plan view of a wafer WF on which a plurality of patterns are formed according to at least one example embodiment. FIG. 4 is a diagram schematically showing large-scale data LSD obtained by measuring a portion of the wafer WF of FIG. 3 according to at least one example embodiment. FIG. 5 is a schematic graph showing uniformity of CDs of contours of a plurality of patterns P included in the large-scale data LSD of FIG. 4 according to at least one example embodiment. FIG. 6 is a diagram showing contours of a plurality of patterns P included in the large-scale data LSD of FIG. 4 as a plurality of clusters C according to at least one example embodiment. FIG. 7 is a schematic graph showing uniformity of CDs of contours of a plurality of patterns P included in each of the plurality of clusters C in FIG. 6 according to at least one example embodiment.

Referring to FIG. 2, the detection method of weak points S100 may include obtaining data corresponding to a plurality of patterns P formed on a wafer WF, e.g., obtaining large-scale data LSD including contours of the plurality of patterns P formed on the wafer WF using a mask (S101), calculating an average value of CDs of the contours of the plurality of patterns P included in the large-scale data LSD (S102), clustering the contours of the plurality of patterns P included in the large-scale data LSD into a plurality of clusters C (S103), calculating an average value of CDs of contours of a plurality of patterns P included in each of the plurality of clusters C (S104), and/or comparing the average value of the CDs of each of the plurality of clusters C with the average value of the CDs of the large-scale data LSD to determine whether each of the plurality of clusters C is a weak point (S105), etc., but the example embodiments are not limited thereto.

Referring to FIG. 3, a plurality of dies D may be formed on the wafer WF through the photolithography process. The plurality of patterns P may be formed on each of the plurality of dies D. The plurality of identical patterns P may be formed on the plurality of dies D. The plurality of patterns P formed on the wafer WF may be photoresist (PR) patterns and/or etch patterns. When obtaining the large-scale data LSD, the plurality of patterns P formed on the wafer WF may be PR patterns and/or etch patterns. For example, the PR pattern may refer to a pattern formed on the PR of the wafer WF when the deposition and/or exposure process has been performed on the wafer WF and the etching pattern may refer to a pattern formed on the wafer WF by performing the exposure process and/or the etching process on the wafer.

Referring to FIG. 4, the large-scale data LSD including the contours of the plurality of patterns P formed on the wafer WF may be obtained. For example, to obtain the large-scale data LSD using, for example, a device with a field of view (FOV) of 1 μm or more, the contours of approximately 100 to approximately 100 million patterns may be measured for approximately 5000 to approximately 10000 points among a plurality of points (e.g., positions, etc.) on the wafer WF, but the example embodiments are not limited thereto and other FOVs may be used to capture and/or obtain the LSD, a different number of patterns and/or a different number of points may be measured, etc. Thus, the large-scale data LSD may include information regarding approximately 5000 points to approximately 10000 points of the wafer WF, but is not limited thereto. The large-scale data LSD may include the contours (e.g., edges, curves, surfaces, etc.) of approximately 100 to approximately 100 million patterns of the wafer WF, but is not limited thereto. The information related to one point included in the large-scale data LSD may include information related to the plurality of patterns. For example, a NGR device may be used to obtain the large-scale data LSD and/or measure the points and/or contours of the plurality of patterns P, but the example embodiments are not limited thereto.

Referring to FIG. 5, the large-scale data LSD may include information about the coordinates and CDs of the contours of the plurality of patterns P. The large-scale data LSD acquired through a large-scale measuring device may be used to determine the uniformity of CDs of the contours of the plurality of patterns P, but is not limited thereto. For example, the quality of a mask may be determined to be better as the uniformity of the CDs of the contours of the plurality of patterns P decreases, etc.

The average value of the CDs of the contours of the plurality of patterns P included in the large-scale data LSD may be calculated. For example, although the layout on the mask has the same size, the plurality of patterns P may have different sizes in the process of forming the plurality of patterns P on the wafer WF due to deviations during the processing of the patterns P, e.g., the exposure process and/or the etching process, etc. The average value of the CDs of the contours of the plurality of patterns P included in the large-scale data LSD may be calculated using a NGR device, but is not limited thereto. For example, the average value of the CDs of the large-scale data LSD may be referred to as an average value of all CDs.

Referring to FIG. 6, the contours of the plurality of patterns P included in the large-scale data LSD may be clustered into a plurality of clusters C, but are not limited thereto. For example, the plurality of patterns P may be clustered into the plurality of clusters C based on the characteristics of the patterns, etc. For example, the plurality of patterns P may have characteristics in relation to surrounding patterns, etc. For example, the characteristics of the patterns may include geometric characteristics and/or image parameter characteristics of the patterns, etc. The geometrical characteristics of the patterns may include the width, height, position, and/or degree of integration of each of the plurality of patterns P, etc. The image parameter characteristics of the patterns may include the maximum/minimum intensity, image log slope, and/or mask error, etc., that occur during the process of simulating a physical optics-based aerial image, but is not limited thereto. In addition, the characteristics of the patterns may be set and/or configured as desired by a user.

For example, the clustering process may be a process of grouping the plurality of patterns P into clusters with similar characteristics, e.g., clustering the plurality of patterns P based on the number of similar characteristics shared between each of the patterns P, the pattern types of the individual patterns P, etc. For example, through the clustering process, similar types of patterns among the plurality of patterns P may be grouped into the same cluster, etc. The clustering process may be performed using unsupervised machine learning using a computer, server, etc., but the example embodiments are not limited thereto. For example, the clustering process may be performed through a K-means clustering technique, but the example embodiments are not limited thereto. For example, the K-means clustering technique is a technique that clusters objects into a desired and/or pre-agreed number of clusters by adjusting the median value of the clusters.

The number of clusters to be clustered may vary depending on the degree to which the characteristics of the patterns are subdivided. The number of clusters may be adjusted, improved and/or optimized based on a silhouette coefficient, but the example embodiments are not limited thereto. The silhouette coefficient may be used as a measure to evaluate cluster adjustment, improvement and/or optimization by calculating the distance between one object (e.g., one pattern) and another object (e.g., another pattern), etc.

The silhouette coefficient may be obtained through s(i)={b(i)−a(i)}/max{a(i), b(i)}, wherein s(i) refers to a silhouette coefficient of object i, a(i) refers to an average of distances between object i and other objects in a cluster to which object i belongs, and b(i) refers to an average of distances between object i and other objects in a cluster closest to the cluster to which object i belongs. The silhouette coefficient may have values of approximately −1 to approximately 1. For example, the object may refer to a pattern type included in each of the plurality of clusters C.

In some example embodiments, the number of clusters may be adjusted, improved, and/or optimized so that the average of silhouette coefficients of each of the plurality of clusters is, e.g., 0.5 or more, but the example embodiments are not limited thereto. For example, when the average of the silhouette coefficients of each of the plurality of clusters is lower than 0.5, the number of clusters may be adjusted until the average of the silhouette coefficients of each of the plurality of clusters is approximately 0.5 to approximately 1, but is not limited thereto.

As shown in FIG. 6, the large-scale data LSD may be clustered into a plurality of clusters, but the example embodiments are not limited thereto, and a different number of clusters may be used. For example, as shown in FIG., the plurality of clusters C may include a first cluster C1, a second cluster C2, a third cluster C3, and a fourth cluster C4, etc. Similar types of patterns may belong to each of the plurality of clusters C (e.g., clusters C1 to C4, etc.). The plurality of clusters C may contain different types of patterns. For example, the types of patterns may be classified according to and/or based on the characteristics of the patterns.

The first cluster C1 may include a first pattern type, the second cluster C2 may include a second pattern type, the third cluster C3 may include a third pattern type, and/or the fourth cluster C4 may include a fourth pattern type, etc., but are not limited thereto, and for example, two or more clusters may have the same pattern type, etc. The first to fourth pattern types may have different geometric characteristics. However, the number of clusters is not limited thereto.

For example, the first cluster C1 may include a plurality of first patterns PT1_1 and a plurality of second patterns PT1_2 which are geometrically similar to each other, the second cluster C may include a plurality of third patterns PT2_1 and a plurality of fourth patterns PT2_2 which are geometrically similar to each other, the third cluster C3 may include a plurality of fifth patterns PT3_1 and a plurality of sixth patterns PT3_2 which are geometrically similar to each other, and the fourth cluster C4 may include a plurality of seventh patterns PT4, etc. Although the plurality of patterns P are clustered based on the geometric characteristics and divided into the plurality of clusters C, the characteristics of the patterns for clustering are not limited thereto.

Referring to FIG. 7, the plurality of patterns P of the large-scale data LSD may be clustered into the plurality of clusters C, thereby grouping the plurality of patterns P into similar types. Accordingly, the uniformity of CDs of the contours of similar types of patterns may be confirmed and/or verified, etc.

For each of the plurality of clusters C, the average value of the CDs of the contours of the plurality of patterns P included in each of the plurality of clusters C may be calculated. The average value of the CDs calculated for each of the plurality of clusters C may be referred to as an average value of the CDs of each of the plurality of clusters C.

For example, the average value of the CDs of the plurality of first patterns PT1_1 and the CDs of the plurality of second patterns PT1_2 may be set as a characteristic of the first cluster C1, the average value of the CDs of the plurality of third patterns PT2_1 and the CDs of the plurality of fourth patterns PT2_2 may be set as a characteristic of the second cluster C2, the average value of the CDs of the plurality of fifth patterns PT3_1 and the CDs of the plurality of sixth patterns PT3_2 may be set as a characteristic of the third cluster C3, and the average value of the CDs of the plurality of seventh patterns PT4 may be set as a characteristic of the fourth cluster C4, etc. For example, a cluster in which the average value of the CDs is set as a characteristic may be referred to as an augmented cluster.

Next, by comparing the average value of the CDs of the large-scale data LSD with the average value of the CDs of each of the plurality of clusters, it may be determined whether each of the plurality of clusters C is and/or includes a weak point. When the average value of the CDs of one of the plurality of clusters C is different from the average value of the CDs of the large-scale data LSD by more than a reference value (e.g., a desired reference value, a weak point threshold value, etc.), the corresponding cluster may be determined to be a weak point. According to at least one example embodiment, the reference value may be a range of approximately 5% to approximately 10% above or below the average value of the CDs of the large-scale LSD, but is not limited thereto. For example, when the average value of the CDs of a cluster differs by more than 5% to 10% from the average value of all CDs, the cluster may be determined to be a weak point, but the example embodiments are not limited thereto. For example, determining that the cluster is a weak point may mean that the one or more patterns and/or the pattern type included in the cluster are/is a weak point.

While the large-scale data LSD is used to determine the uniformity of the CDs of the plurality of patterns P in conventional mask quality detection methods, according to one or more example embodiments of the inventive concepts, the large-scale data LSD may be clustered into the plurality of clusters C and may be used to determine whether each of the plurality of clusters C is and/or includes a weak point in the detection method of mask quality. Accordingly, new weak points may be detected in patterns in addition to pre-stored and/or previously identified weak points and thus a variety and/or plurality of weak points may be used to test and verify the mask quality.

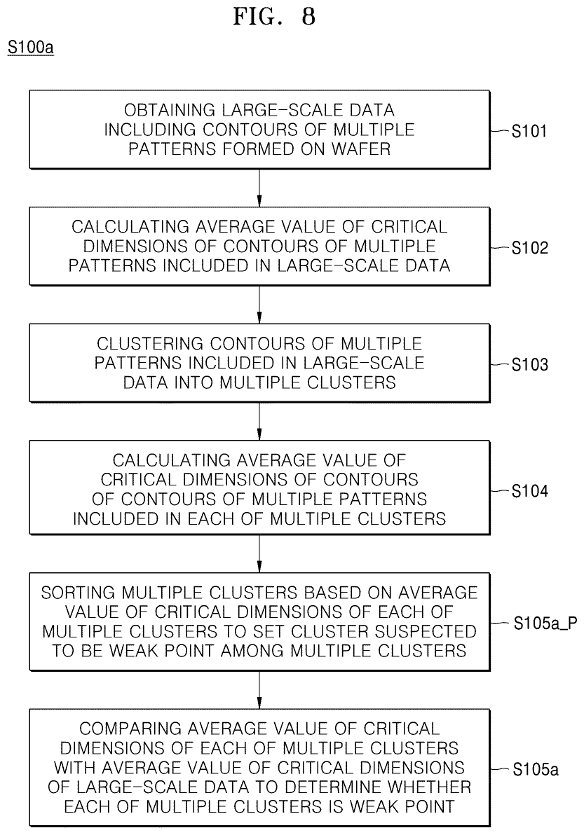

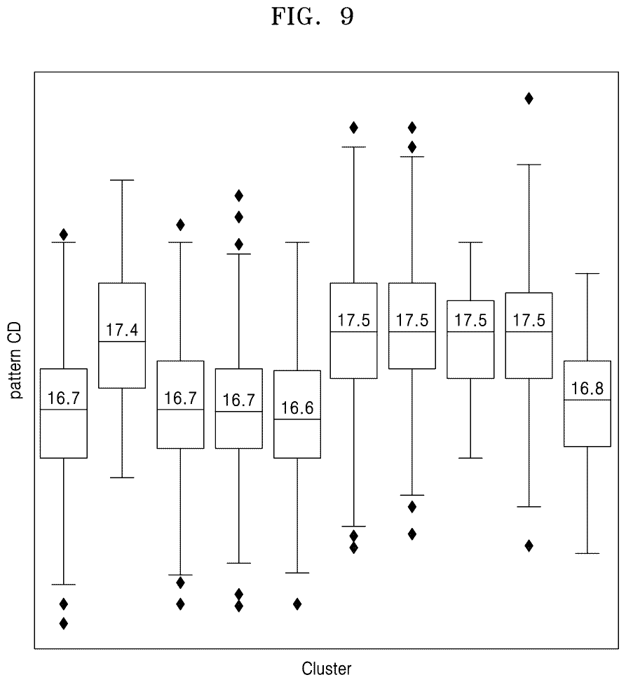

FIG. 8 is a schematic flowchart of a detection method of weak points S100a according to at least one example embodiment. FIG. 9 is a schematic graph showing an average value of CDs for each cluster C (see FIG. 6) according to at least one example embodiment. Specifically, FIG. 9 is a graph illustrating, for each cluster, the average value and uniformity of the CDs of each cluster.

Referring to FIG. 8, the detection method of weak points in a mask design S100a may include obtaining large-scale data including contours of a plurality of patterns formed on a semiconductor wafer using a mask (S101), calculating an average value of CDs of the contours of the plurality of patterns included in the large-scale data (S102), clustering the contours of the plurality of patterns included in the large-scale data into a plurality of clusters (S103), calculating an average value of CDs of contours of the plurality of patterns included in each of the plurality of clusters (S104), sorting the plurality of clusters based on the average value of the CDs of each of the plurality of clusters to set a cluster suspected to be a weak point among the plurality of clusters (S105a_P), and/or comparing the average value of the CDs of each of the plurality of clusters with the average value of the CDs of the large-scale data to determine whether any of the plurality of clusters is a weak point (S105a), etc., but the example embodiments are not limited thereto.

Some of the operations for configuring the detection method of weak points in a mask design S100a described below are the same, substantially the same, or similar to those previously described with reference to FIG. 2. Therefore, for sake of brevity and clarity, the description is made focusing on the difference between the detection method of weak points S100a of FIG. 8 and the detection method of weak points S100 of FIG. 2.

Referring to FIGS. 8 and 9 together with FIGS. 6 and 7, the detection method of weak points in a mask design S100a may further include sorting the plurality of clusters C to set and/or identify a cluster suspected to be a weak point. The average value of the CDs of each of the plurality of clusters C may be sorted based on the average value of the CDs of the increased clusters set as the characteristic of each of the plurality of clusters C. For example, the plurality of clusters C may be sorted in descending or ascending order of the average value of the CDs of each of the plurality of clusters C, or in other words, sorted in order of most likely to least likely cluster to be a weak point among the plurality of clusters C, etc.

By sorting the plurality of clusters C so that average values of the CDs are sequential, the uniformity of the average values of the CDs, the maximum and/or highest of the average values of the CDs, and the minimum and/or lowest of the average values of the CDs may be quickly determined.

In some example embodiments, as the plurality of clusters C are sorted in order of the size of the average values of the CDs, the upper cluster and/or lower cluster may be set as clusters suspected to be weak points. For example, the upper cluster may be a cluster that falls within the top 5% of the plurality of sorted clusters C average CD value and the lower cluster may be a cluster that falls within the bottom 5% of the plurality of sorted clusters C average CD value, etc. However, the percentiles of the upper cluster and lower cluster are not limited thereto and may vary depending on the uniformity of the average values of the CDs of the sorted clusters, etc.

In some example embodiments, after sorting the plurality of clusters C in order of size of the average values of the CDs, an upper group including clusters of which the average value of the CDs is different by less than 10% from the average value of the CDs of the first cluster and/or a lower group including clusters of which the average value of the CDs is different by less than 10% from the average value of the CDs of the last cluster may be set as clusters suspected to be weak points, etc.

When determining and/or verifying the weak points of the mask design, only the clusters suspected to be weak points may be subject to the determination (e.g., weak point testing, weak point analysis, etc.) by setting some of the plurality of clusters C as clusters suspected to be weak points based on the average values of the CDs of the plurality of clusters C, but the example embodiments are not limited thereto, and for example, additional clusters and/or all of the clusters may be verified to determine if they include weak points, etc. For example, when determining weak points, the average value of the CDs of each cluster suspected to be a weak point may be compared with the average value of the CDs of the large-scale data to determine whether the cluster suspected to be a weak point is an actual, verified, and/or determined weak point. By reducing the range of targets for determining weak points from every cluster of the plurality of clusters C to a subset of clusters of the plurality of clusters C suspected to be weak points, the time and/or cost required in the weak point detection process may be reduced.

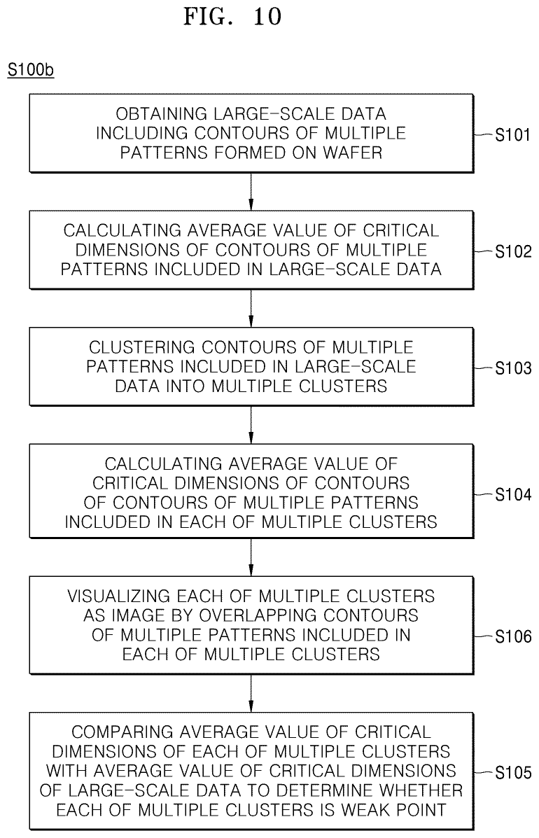

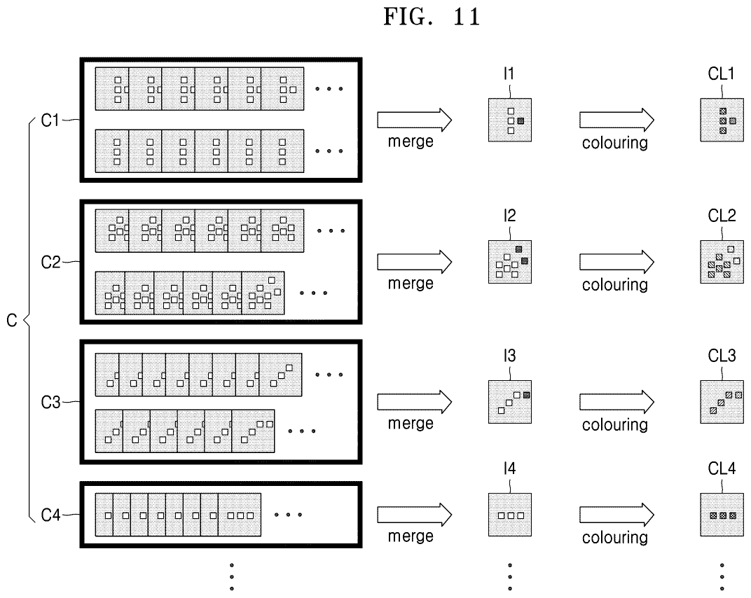

FIG. 10 is a schematic flowchart of a detection method of weak points S100b according to at least one example embodiment. FIG. 11 is a diagram showing a process of visualizing each of a plurality of clusters C according to at least one example embodiment.

Referring to FIG. 10, the detection method of weak points in the mask design S100b may include obtaining large-scale data including the contours of a plurality of patterns formed on a wafer using a mask (S101), calculating an average value of CDs of the contours of the plurality of patterns included in the large-scale data (S102), clustering the contours of the plurality of patterns included in the large-scale data into a plurality of clusters (S103), calculating an average value of CDs of contours of the plurality of patterns included in each of the plurality of clusters (S104), visualizing each of the plurality of clusters as an image by overlapping the contours of the plurality of patterns included in each of the plurality of clusters (S106), and/or comparing the average value of the CDs of each of the plurality of clusters with the average value of the CDs of the large-scale data to determine whether any of the plurality of clusters is a weak point (S105), etc.

In some example embodiments, the detection method of weak points S100b may further include sorting the plurality of clusters based on the average value of the CDs of each of the plurality of clusters to set at least one cluster as being suspected to be a weak point among the plurality of clusters S105a_P (see FIG. 8). As previously described with reference to FIG. 8, the detection method of weak points S100b may only target clusters suspected to be weak points in the process of determining whether they are verified and/or actual weak points, but the example embodiments are not limited thereto.

The operations of configuring the detection method of weak points S100b described below are same, substantially the same, and/or similar to those previously described with reference to FIG. 2. Therefore, for the sake of brevity and clarity, the description is made focusing on the difference between the detection method of weak points S100b of FIG. 8 and the detection method of weak points S100 of FIG. 2.

The detection method of weak points S100b may include visualizing the plurality of clusters to be easily distinguished by the user. FIG. 11 briefly shows the visualization process after clustering the large-scale data into the plurality of clusters C. The plurality of patterns included in the large-scale data may be grouped into the plurality of clusters C based on the characteristics of the patterns. Each of the plurality of clusters C may include similar pattern types, but are not limited thereto.

Referring to FIG. 11, by overlapping the contours of the plurality of patterns included in each of the plurality of clusters C, each of the plurality of clusters C may be converted into a single image. The pattern types included in each of the plurality of clusters C may be overlapped to form one image.

In some example embodiments, the contours of the plurality of patterns included in each of the plurality of clusters C may be dithered and overlapped. Dithering is a method of reducing the number of bits of contours of a plurality of patterns and may suppress noise generation, etc., in the process of overlapping the contours of the plurality of patterns.

For example, the first cluster C1 may include the plurality of first patterns PT1_1 (see FIG. 6) and the plurality of second patterns PT1_2 (see FIG. 6). By overlapping the plurality of first patterns with the plurality of second patterns included in the first cluster C1, the plurality of first patterns and the plurality of second patterns may be converted into one first image I1. A plurality of patterns included in the second cluster C2 may also be overlapped and converted into a second image I2, a plurality of patterns included in the third cluster C3 may also be overlapped and converted into a third image I3, and/or a plurality of patterns included in the fourth cluster C4 may also be overlapped and converted into the fourth image I4, etc.

The contours of the plurality of patterns included in each of the plurality of clusters C may not completely match although the pattern types are similar. Accordingly, in the process of overlapping the contours of the plurality of patterns, there may be contours of patterns that overlap a relatively large amount and contours of patterns that overlap relatively little. For example, common pattern characteristics of the plurality of patterns included in one cluster may allow the contours of patterns to overlap a relatively large amount and pattern characteristics of some of the plurality of patterns included in one cluster may allow the contours of patterns to overlap relatively little.

In some example embodiments, the image of each of the plurality of clusters C may be visualized so that the brightness, color, and/or pixel values increases as more contours overlap, but the example embodiments are not limited thereto. In each image of the plurality of clusters C, an area where the common pattern characteristics of the plurality of patterns included in the cluster are shown may appear brighter than other areas. The user and/or computer analysis may quickly identify the pattern type of each cluster through image analysis of each cluster C, etc., but the example embodiments are not limited thereto. For example, a computer executing a trained machine learning algorithm may identify the pattern type of each cluster using the image of each of the plurality of clusters C based on the pixel values of the image.

For example, in the first image I1 of the first cluster C1, the common pattern characteristics of the plurality of patterns included in the first cluster C1 may be visualized so that the brightness increases and/or color changes compared to the pattern characteristics of some of the plurality of patterns, etc. In the second image I2 of the second cluster C2, the common pattern characteristics of the plurality of patterns included in the second cluster C2 may be visualized so that the brightness increases and/or color changes compared to the characteristics of the patterns having only some of the plurality of patterns, etc. In the third image I3 of the third cluster C3, the common pattern characteristics of the plurality of patterns included in the third cluster C3 may appear to have increased brightness and/or a different color compared to the pattern characteristics of some of the plurality of patterns, etc.

For example, in the process of obtaining the large-scale data by measuring patterns formed on the wafer, points where patterns are formed in the large-scale data may be stored as values with relatively high brightness and/or a first desired color indicating similarity, and points where patterns are not formed in the large-scale may be stored as values with relatively low brightness and/or a second desired color indicating dissimilarity, etc., but are not limited thereto. Accordingly, in the process of creating an image by clustering the large-scale data into a plurality of clusters and overlapping the same, the brightness and/or color may be visualized to increase and/or adjust as the contours overlap, etc.

In some example embodiments, a plurality of filtering processes may be performed on the image of each of the plurality of clusters C. For example, the filtering processes may be performed on each image of the plurality of clusters C based on pixel values. For example, the filtering processes may include at least one of thresholding and/or a Gaussian filter, etc., but are not limited thereto.

The thresholding may be a filter that binarizes pixel values in an image using a user-specified reference value, and the Gaussian filter may be a filtering technique that uses a filter mask created by approximating a Gaussian distribution function. The Gaussian distribution refers to a probability distribution that has a symmetrical bell shape around the mean. Through the thresholding and Gaussian filter, the occurrence of noise may be suppressed in each image of the plurality of clusters C.

In some example embodiments, each image of the plurality of clusters C may be colored. For example, different colors may be applied to each image of the plurality of clusters C. The user may view the image of each of the plurality of clusters C and quickly identify differences between the clusters.

For example, a first color may be applied to the first image I1 to form a first color image CL1, a second color may be applied to the second image I2 to form a second color image CL2, a third color may be applied to the third image I3 to form a third color image CL3, and a fourth color may be applied to the fourth image I4 to form a fourth color image CL4. For example, the first color, the second color, the third color and the fourth color may be different from each other.

In some example embodiments, different colors may be applied to the image of each of the plurality of clusters C, corresponding to the average value of the CDs of each of the plurality of clusters C. For example, after sorting the plurality of clusters C so that the average value of the CDs of each of the plurality of clusters C is in descending order, each image of the plurality of clusters C may be colored so that the color gradually changes from the first cluster to the last cluster. The user and/or a computer executing an image analysis algorithm may quickly identify the cluster suspected to be a weak point based on the color of each image of the plurality of clusters C.

In some example embodiments, if the image of each of the plurality of clusters C includes a first portion and a second portion with different brightnesses, the colors of the first portion and the second portion may be different in brightness when coloring each image of the plurality of clusters C. For example, although the image is colored, the difference in brightness of each portion of the image may be maintained.

While various example embodiments of the inventive concepts have been particularly shown and described, it will be understood that various changes in form and details may be made therein without departing from the spirit and scope of the following claims.

What is claimed is:

1. A detection method of weak points, the method comprising:
obtaining large-scale data including contours of a plurality of patterns formed on a wafer using a mask;
calculating an average value of critical dimensions of the contours of the plurality of patterns included in the large-scale data;
clustering the plurality of patterns into a plurality of clusters based on characteristics of the plurality of patterns;
calculating, for each of the plurality of clusters, an average value of the critical dimensions of the contours of the plurality of patterns included in each of the plurality of clusters; and
determining whether one or more clusters of the plurality of clusters are weak points based on the average value of the critical dimensions of each of the plurality of clusters and the average value of the critical dimensions of the large-scale data.

2. The detection method of weak points of claim 1, wherein the large-scale data comprises contours between 100 to 100 million patterns.

3. The detection method of weak points of claim 1, wherein each of the plurality of patterns formed on the wafer includes an etch pattern.

4. The detection method of weak points of claim 1, wherein the characteristics of the plurality of patterns comprise at least one of geometric characteristics, and image parameter characteristics of the patterns, or a combination thereof.

5. The detection method of weak points of claim 1, wherein the clustering of the plurality of patterns comprises clustering the plurality of patterns into the plurality of clusters using a K-means clustering technique.

6. The detection method of weak points of claim 5, wherein the clustering of the plurality of patterns comprises adjusting a number of the plurality of clusters so that an average of silhouette coefficients of each of the plurality of clusters is between 0.5 to 1.

7. The detection method of weak points of claim 1, wherein the determining whether the one or more clusters of the plurality of clusters are weak points comprises:
identifying, among the plurality of clusters, at least one cluster having an average value of the critical dimensions that is different by between 5% to 10% from the average value of the critical dimensions of the large-scale data; and
determining the identified at least one cluster as being a weak point.

8. The detection method of weak points of claim 1, further comprising:
sorting the plurality of clusters based on an average value of the critical dimensions calculated for each of the plurality of clusters; and
setting at least one cluster suspected to be a weak point among the plurality of clusters based on results of the sorting.

9. The detection method of weak points of claim 8, wherein the sorting the plurality of clusters comprises sorting the plurality of clusters in descending order based on the average value of the critical dimensions of each of the plurality of clusters.

10. The detection method of weak points of claim 8, wherein the determining whether the one or more clusters of the plurality of clusters are weak points comprises only testing the at least one cluster suspected to be a weak point among the plurality of clusters.

11. A detection method of weak points, the method comprising:
obtaining large-scale data including contours of a plurality of patterns formed on a wafer using a mask;
clustering the plurality of patterns into a plurality of clusters based on characteristics of the plurality of patterns;
calculating, for each respective cluster of the plurality of clusters, an average value of critical dimensions of the contours of the plurality of patterns included in the respective cluster;
visualizing each of the plurality of clusters as an image, the visualizing including for each respective cluster of the plurality of clusters, overlapping the contours of the plurality of patterns included in the respective cluster; and
determining whether one or more of the plurality of clusters include weak points based on the average value of the critical dimensions of each of the plurality of clusters and the average value of the critical dimensions of the large-scale data.

12. The detection method of weak points of claim 11, wherein the visualizing of each of the plurality of clusters comprises, for each respective cluster of the plurality of clusters:
dithering and overlapping the contours of the plurality of patterns included in the respective cluster.

13. The detection method of weak points of claim 11, wherein the visualizing of each of the plurality of clusters comprises, for each respective cluster of the plurality of clusters:
adjusting brightness values associated with each of the contours included in the image based on a degree of overlap of the contours included in the respective cluster.

14. The detection method of weak points of claim 11, wherein the visualizing of each of the plurality of clusters comprises, for each respective cluster of the plurality of clusters:
applying different colors to the image based on a degree of overlap of the contours included in the respective cluster.

15. The detection method of weak points of claim 11, further comprising:
sorting the plurality of clusters based on an average value of the critical dimensions calculated from each of the plurality of clusters; and
setting at least one cluster suspected to be a weak point among the plurality of clusters based on results of the sorting.

16. A verification method of mask quality, the method comprising:
forming a plurality of patterns on a wafer through a photolithography process using a mask;
obtaining basic data of the plurality of patterns formed on the wafer;
detecting weak points based on the basic data; and
determining whether the mask is defective based on the detected weak points, the detecting of the weak points including,
obtaining large-scale data including contours of the plurality of patterns formed on the wafer using the mask,
calculating an average value of critical dimensions of the contours of the plurality of patterns included in the large-scale data,
clustering the plurality of patterns into a plurality of clusters based on characteristics of the plurality of patterns,
calculating, for each respective cluster of the plurality of clusters, an average value of the critical dimensions of the contours of the plurality of patterns included in the respective cluster, and
determining whether one or more of the plurality of clusters are weak points based on the average value of the critical dimensions of each of the plurality of clusters and the average value of the critical dimensions of the large-scale data.

17. The verification method of mask quality of claim 16, wherein the detecting the weak points comprises detecting the weak points using simulation of the basic data.

18. The verification method of mask quality of claim 16, wherein the determining whether one or more of the plurality of clusters are weak points comprises:
identifying, among the plurality of clusters, at least one cluster having an average value of the critical dimensions that is different by between 5% to 10% from the average value of the critical dimensions of the large-scale data; and
setting the identified at least one cluster as including a weak point.

19. The verification method of mask quality of claim 16, wherein
the detecting of the weak points comprises,
sorting the plurality of clusters based on an average value of the critical dimensions calculated from each of the plurality of clusters, and
setting at least one cluster suspected to be a weak point among the plurality of clusters based on results of the sorting; and
the determining whether one or more of the plurality of clusters are weak points comprises,
testing only the at least one cluster suspected to be a weak point among the plurality of clusters.

20. The verification method of mask quality of claim 16, wherein the detecting the weak points comprises:
visualizing each of the plurality of clusters as an image, the visualizing including, for each respective cluster of the plurality of clusters, overlapping the contours of the plurality of patterns included in of the respective cluster; and
applying, for each of the plurality of clusters, different colors to the image of based on a degree of overlap of the contours included in the respective cluster.
